(19) United States
(12) Patent Application Publication
(10) Pub. No.: US 2006/0045666 A1
(43) Pub. Date: Mar. 2, 2006

(54) Modular tool unit for processing of microfeature workpieces

(76) Inventors: Randy A. Harris, Kalispell, MT (US); Paul Wirth, Columbia Falls, MT (US)

Correspondence Address: PERKINS COIE LLP, P.O. BOX 1247, PATENT-SEA, SEATTLE, WA, 98111-1247, US

(21) Appl. No.: 11/178,241

(22) Filed: Jul. 7, 2005

Related U.S. Application Data
(60) Provisional application No. 60/586,833, filed on Jul. 9, 2004.

(51) Int. Cl. H01L 21/677

(52) U.S. Cl. 414/217

(57) ABSTRACT

A modular tool unit for wet chemical processing of microfeature workpieces including a dimensionally stable mounting module having front alignment elements at predetermined locations, positioning elements, and attachment elements. The tool unit further includes a wet chemical processing chamber and a transport system attached to the mounting module. The wet chemical processing chamber has chamber interface members engaged with corresponding positioning elements and chamber fasteners engaged with corresponding attachment elements. Similarly, the transport system has transport interface members engaged with corresponding positioning elements and transport fasteners engaged with corresponding attachment elements. The positioning elements for the wet chemical processing chamber and the transport system are precisely located at known points within the fixed reference frame defined by the dimensionally stable mounting module.

### TECHNICAL FIELD

The present invention is directed toward a modular apparatus and methods of using such an apparatus for processing microfeature workpieces having a plurality of microdevices integrated in and/or on the workpieces. Particular aspects of the present invention are directed toward dimensionally stable mounting modules to provide a universal platform for assembling wet chemical processing chambers, other types of processing stations, and/or robotic transport systems.

### BACKGROUND

Microdevices are manufactured by depositing and working several layers of materials on a single substrate to produce a large number of individual devices. For example, layers of photoresist, conductive materials, and dielectric materials are deposited, patterned, developed, etched, planarized, and otherwise manipulated to form features in and/or on a substrate. The features are often arranged to form integrated circuits, micro-fluidic systems, and other structures. Wet chemical processes are commonly used to form features on microfeature workpieces, clean the surface of workpieces, etch material from the workpieces and/or otherwise prepare the workpieces for subsequent processing. Wet chemical processes are generally performed in wet chemical processing tools that have a plurality of individual processing chambers for cleaning, etching, electrochemically depositing materials, or performing combinations of these processes. The processing chambers can accordingly be rinse/dry chambers, cleaning capsules, etching capsules, electrochemical deposition chambers, or other types of wet chemical processing chambers. Other processes, such as annealing, metrology, planarization, etc., are used to further process or analyze layers on the workpieces.

A typical wet chemical processing tool includes a housing or cabinet having a platform, a plurality of wet chemical processing chambers in the cabinet, and a transport system. The tool can further include separate robots that raise and lower a head portion of the processing chambers for loading/unloading workpieces. The transport system can have several different configurations. In a linear configuration, the transport system includes a linear track and a robot that moves along the track to transport individual workpieces within the tool. The transport system can also access cassettes or pods at a load/unload module before and after they have been processed in the tool.

Automated handling of workpieces is an important aspect of manufacturing microelectronic devices. In general, a robot must accurately move workpieces among different processing chambers and other stations within a single tool. For example, many robots move workpieces to/from six to ten processing chambers and two to three pods. A linear track robot typically moves the workpieces among the processing chambers and the pods by moving along the track, rotating one or more links about several pivot points, and raising/lowering the workpiece in a variety of complex motions.

One challenge of handling workpieces is accurately calibrating the transport system to move workpieces to/from the processing chambers and the pods. The transport system is typically calibrated by manually “teaching” the robot the specific positions of each chamber and each pod. For example, conventional calibration processes involve manually positioning the robot at a desired location with respect to each chamber and pod, and recording encoder values corresponding to the positions of the robot at each of these components. The encoder value is then inputted as a program value for the software that controls the motion of the robot. In addition to manually teaching the robot the specific locations within the tool, the arms and end-effectors of the robot are also manually aligned with the reference frame in which the program values are represented as coordinates. Although the process of manually aligning the components of the robot to the reference frame and manually teaching the robot the location of each component in the tool is an accepted method for setting up a tool, it is also extremely time-consuming and subject to operator error. For example, it takes approximately six to eight hours to align the robot to the reference frame and then teach the robot the locations of ten chambers and two pods. Moreover, the quality of each program value is subject to operator error because it is often difficult to accurately position the robot in one or more of the chambers or containers.

Another challenge of operating integrated wet chemical processing tools is repairing/maintaining the processing chambers. Electrochemical deposition chambers, for example, require periodic maintenance because they have consumable electrodes that degrade over time. Additionally, byproducts from organic additives can collect in the plating solution such that the processing solution is changed periodically. One problem with repairing or maintaining existing wet chemical processing chambers is that the tool must be taken offline for an extended period of time to replace the chamber and manually recalibrate the robot. In fact, when only one processing chamber of a tool does not meet the specifications, it is often more efficient to continue operating conventional tools without stopping to repair the one out-of-specification processing chamber until more processing chambers do not meet the performance specifications. The loss of throughput of a single processing chamber, therefore, is not as severe as a loss of throughput caused by taking the tool offline to repair or maintain a single one of the processing chambers.

The practice of operating the tool until at least two processing chambers do not meet specifications severely impacts the throughput of the tool. For example, if the tool is not repaired or maintained until at least two or three processing chambers are out of specification, then the tool operates at only a fraction of its full capacity for a period of time before it is taken offline for maintenance. This increases the operating costs of the tool because the throughput not only suffers while the tool is offline to replace the wet chemical processing chambers and to reteach the robot, but the throughput is also reduced while the tool is operating because it operates at only a fraction of its full capacity. Moreover, as the feature sizes decrease, the electrochemical deposition chambers must consistently meet higher performance specifications. This causes the processing chambers to fall out of specifications sooner, which results in taking the tool offline more frequently. Therefore, the downtime associated with calibrating the transport system and repairing/maintaining electrochemical deposition chambers significantly impacts the costs of operating wet chemical processing tools.

These challenges are not limited to operating wet chemical processing tools, but rather other tools face similar challenges. For example, wafers are moved to/from annealing and metrology stations using automated handling equipment, and thus it is time-consuming to align robots with these types of processing stations as well.

Another aspect of wet chemical processing tools is cost-effectively manufacturing and installing the tools to meet demanding customer specifications. Many microelectronic companies develop proprietary processes that require custom wet chemical processing tools and/or other types of processing stations. For example, individual customers may need different combinations and/or different numbers of wet chemical processing chambers, annealing stations, metrology stations, and/or other components to optimize their process lines. Manufacturers of wet chemical processing tools accordingly custom build many aspects of each tool to provide the functionality required by the particular customer and to optimize floor space, throughput, and reliability.

To meet the requirements of each individual customer, tool manufacturers typically produce tools having a main processing unit with a platform configured for a specific number of processing chambers and/or other types of stations. Tool manufacturers must accordingly provide several different platform configurations depending upon whether the individual customers require 2, 4, 6, 8, 10, etc., processing stations in a tool. It is expensive and inefficient to manufacture a large number of different platform configurations to meet the needs of the individual customers. Therefore, there is also a need to improve the cost-effectiveness for manufacturing wet chemical processing tools.

### SUMMARY

One aspect of the present invention is directed toward a modular tool unit that has a dimensionally stable mounting module, a transport system, and a calibration system for quickly aligning a robot of the transport system to the platform. The modular tool unit can be a stand-alone unit that operates by itself, or a plurality of modular tool units can be connected together to customize the configuration of a particular tool. As explained in more detail below, the dimensionally stable mounting module enables individual modular tool units to be connected together in a manner that maintains relative positions between individual processing chambers and the transport system in a fixed reference frame defined by one of the mounting modules. One benefit of the modular tool units is that each tool unit can have a small number of processing stations (e.g., two), and that a number of modular tool units can be connected together to produce different configurations of processing chambers. As such, tool manufacturers can use a universal modular tool unit to produce different tools with different configurations of processing stations in a manner that enhances the efficiency of manufacturing custom integrated tool assemblies.

Another aspect of the present invention is that the robot can be automatically calibrated to work with the individual processing chambers in a short period of time. Because the mounting module is dimensionally stable, the processing chambers/stations and the transport system can be attached to the mounting module at precise locations in a fixed reference frame. As a result, once the robot is aligned with the fixed reference frame defined by the mounting module, the robot can interface with the processing chambers or other stations without having to be manually taught the location of each specific station. Therefore, modular tool units with automated calibration systems in accordance with several embodiments of the invention are expected to reduce the downtime associated with installing and/or maintaining wet chemical processing tools.

Still another aspect of the present invention is directed toward an integrated tool that enables wet chemical processing chambers, lift-rotate units, and other hardware to be quickly interchanged or reconfigured without having to recalibrate the transport system or other components of the tool. This is expected to reduce the time associated with assembling, repairing, or maintaining processing chambers and/or lift-rotate units so that the tool is less expensive to manufacture and can operate for longer periods of time. As such, several aspects of the invention are particularly useful for applications that require stringent performance specifications because the tool is more likely to have the correct dimensions in the first place and the processing chambers can be quickly interchanged to reduce downtime for repair/maintenance.

One embodiment of a modular tool unit for wet chemical processing of microfeature workpieces includes a dimensionally stable mounting module including a front section having front alignment elements at predetermined locations, a processing section behind the front section, positioning elements, and attachment elements. The tool unit further includes a wet chemical processing chamber attached to the processing section of the mounting module and a transport system at the front section of the mounting module. The wet chemical processing chamber has chamber interface members engaged with corresponding positioning elements and chamber fasteners engaged with corresponding attachment elements. Similarly, the transport system has transport interface members engaged with corresponding positioning elements and transport fasteners engaged with corresponding attachment elements. The positioning elements for the wet chemical processing chamber and the transport system are precisely located at known points within the fixed reference frame defined by the dimensionally stable mounting module. As such, the mounting module positions the wet chemical processing chamber and the transport system at known locations in the fixed reference frame such that the transport system can automatically interface with the processing chambers or other stations in the modular tool unit.

In another embodiment, the modular tool unit can further comprise a dimensionally stable load/unload module having a first docking unit with first alignment elements arranged in a pattern of the predetermined locations of the front alignment elements on the mounting module. The first alignment elements of the load/unload module are engaged with the front alignment elements of the mounting module to precisely position the load/unload module with respect to the fixed reference frame of the mounting module. As a result, the transport system is also aligned with the appropriate workpiece containers of the load/unload module without having to manually teach the robot the locations of the containers.

In additional embodiments, a plurality of modular tool units that each have a dimensionally stable mounting module can be coupled together with one or more dimensionally stable load/unload modules to customize the configuration of a particular tool. Because the mounting modules of the modular tool units are dimensionally stable, a first tool unit can be coupled to a second tool unit such that the processing stations in the second tool unit are precisely located at known locations in the fixed reference frame of the first tool unit. This enables tool manufacturers to produce a universal deck configuration that can be used to produce several different configurations of processing chambers for customizing individual tools. This is expected to significantly enhance the cost-effectiveness and efficiency of manufacturing wet chemical processing tools.

### BRIEF DESCRIPTION OF THE DRAWINGS

FIG. 1A is a top plan view illustrating a modular tool unit with a load/unload module in accordance with an embodiment of the invention. Several features of the modular tool unit illustrated in FIG. 1A are shown schematically.

FIG. 1B is a top plan view of the modular tool unit shown in FIG. 1A, and several features of the modular tool unit in FIG. 1B are illustrated schematically.

FIG. 2 is a top plan view of a modular tool unit with a load/unload module in accordance with an embodiment of the invention, and several features of the tool unit are shown schematically in FIG. 2.

FIG. 3 is a top plan view of an integrated tool assembly having a plurality of modular tool units in accordance with an embodiment of the invention. Several features of the integrated tool assembly are shown schematically in FIG. 3.

FIG. 4A is a front isometric view of a modular tool unit with a load/unload module in accordance with another embodiment of the invention.

FIG. 4B is a rear isometric view of the modular tool unit shown in FIG. 4A.

FIG. 4C is a top plan view of the modular tool unit shown in FIGS. 4A and 4B.

FIG. 5 is a cross-sectional view illustrating a portion of a mounting module for use in a modular tool unit in accordance with an embodiment of the invention.

FIG. 6 is a detailed view of the portion of the mounting module illustrated in FIG. 5.

FIG. 7A is a rear isometric view of a door assembly for use with a load/unload module in accordance with an embodiment of the invention.

FIG. 7B is a front isometric view of the door assembly shown in FIG. 7A.

### DETAILED DESCRIPTION

As used herein, the terms “microfeature workpiece” or “workpiece” refer to substrates on and/or in which microelectronic devices are formed integrally. Typical microdevices include microelectronic circuits or components, thin-film recording heads, data storage elements, microfluidic devices, and other products. Micromachines or micromechanical devices are included within this definition because they are manufactured using much of the same technology that is used in fabricating integrated circuits. The substrates can be semiconductive pieces (e.g., doped silicon wafers or gallium arsenide wafers), dielectric pieces (e.g., various ceramic substrates), or conductive pieces.

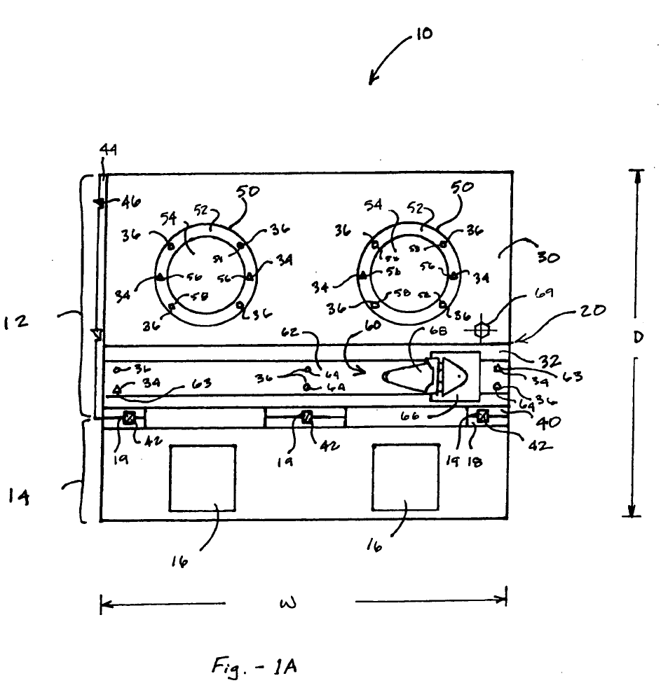

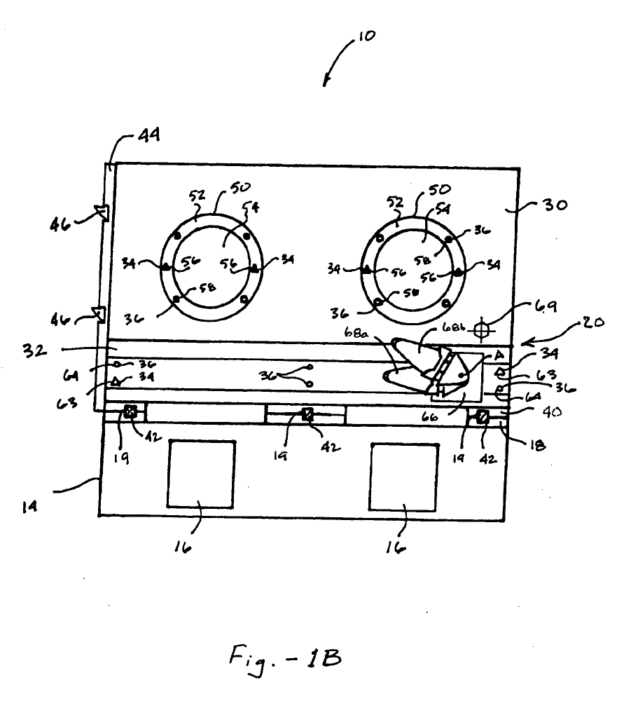

Several embodiments of integrated tools for wet chemical processing are described in the context of depositing metals or electrophoretic resist in or on structures of a workpiece. The integrated tools in accordance with the invention, however, can also be used for other wet chemical processes (e.g., etching or rinsing) or other types of processes (e.g., annealing or metrology) in the fabrication of microfeatures in and/or on semiconductor substrates or other types of workpieces. Several embodiments of tools in accordance with the invention are set forth in FIGS. 1A-7B, and the following text provides a thorough understanding of particular embodiments of the invention. A person skilled in the art will understand that the invention may have additional embodiments, or that the invention may be practiced without several of the details of the embodiments shown in FIGS. 1A-7B.

### A. Embodiments of Modular Tool Units

FIG. 1A is a top plan view of a modular tool unit 10 in accordance with one embodiment of the invention. In this embodiment, the modular tool unit 10 includes a processing module 12 and a load/unload module 14. The processing module 12 includes a mounting module 20, processing stations 50 attached to one portion of the mounting module 20, and a transport system 60 attached to another portion of the mounting module 20. The load/unload module 14 includes workpiece holders 16 for holding workpieces before and after being processed in the processing stations 50.

The mounting module 20 is a rigid, stable structure that maintains the relative positions between the processing stations 50 and the transport system 60. One aspect of the mounting module 20 is that it defines a fixed reference frame because it is much more rigid and has significantly greater structural integrity than conventional processing platforms for holding wet chemical processing chambers. Another aspect of the mounting module 20 is that it includes positioning elements that engage corresponding chamber interface members to position the processing stations 50 at precise locations in the fixed reference frame of the mounting module 20. The mounting module 20 accordingly provides a system in which wet chemical processing chambers, other types of processing stations, transport systems, load/unload modules, and other modular tool units can be assembled in a manner that accurately positions the components at precise locations so that the transport system 60 can be easily calibrated to work with the various components.

The mounting module 20 illustrated in FIG. 1A includes a dimensionally stable deck 30 and a dimensionally stable platform 32. As explained in more detail below, the deck 30 can be made from a plurality of panels and bracing that form a strong, rigid structure which maintains precise dimensions. The mounting module 20 further includes a plurality of positioning elements 34 at precise predetermined locations in the fixed reference frame of the mounting module 20 and a plurality of attachment elements 36. In general, the mounting module 20 has two or more positioning elements 34 and two or more attachment elements 36 at each processing site on the deck 30. The mounting module 20 also has positioning elements 34 and attachment elements 36 at the platform 32 that interface with the transport system 60. The positioning elements 34 can be pins or holes that mate with a corresponding structure of a chamber or transport system 60. The attachment elements 36 can be threaded studs or threaded holes to engage a corresponding structure of the processing chambers and the transport system 60.

The mounting module 20 can further include a front docking unit 40 at the front side of the platform 32. The front docking unit 40 can include a plurality of front alignment elements 42 at predetermined locations in the fixed reference frame of the mounting module 20. The docking unit 40 can be a panel of 0.25 inch stainless steel fixedly attached to the platform 32 to remain dimensionally stable in the fixed reference frame of the mounting module 20. The load/unload unit 14 can further include a first docking unit 18 having first alignment elements 19. The first docking unit 18 can be a 0.25 inch panel of stainless steel, and the first alignment elements 19 are configured to engage the front alignment elements 42 of the front docking unit 40 to accurately align the workpiece holders 16 with the fixed reference frame of the mounting module 20.

The mounting module 20 can optionally include a side docking unit 44 having a plurality of side alignment elements 46 for connecting a second modular mounting tool unit (not shown in FIG. 1A) to the modular tool unit 10. The side docking unit 44 can be a 0.25 inch panel of stainless steel fixedly attached to the deck 30 and the platform 32 so that the side alignment elements 46 are at predetermined locations in the fixed reference frame of the mounting module 20. An integrated tool assembly having a plurality of modular tool units connected at the side docking units is described in more detail below with reference to FIG. 3.

The processing stations 50 in the embodiment illustrated in FIG. 1A include a flange 52 and a vessel 54 attached to the flange 52. The flange 52 is a dimensionally stable component that includes chamber interface members 56 at predetermined locations relative to the vessel 54 and chamber fasteners 58. The chamber interface members 56 are arranged in a pattern to mate with corresponding positioning elements 34 at a processing station on the deck 30. The fit between the positioning element 34 and the chamber interface members 56 is very tight so that the vessel 54 is positioned precisely at a predetermined location with respect to the fixed reference frame of the mounting module 20 when the chamber interface members 56 are engaged with corresponding positioning elements 34 on the deck 30.

The processing stations 50 can be electrochemical deposition chambers, spin-rinse-dry chambers, cleaning capsules, etching chambers, or other suitable wet chemical processing stations. In the case of electrochemical deposition chambers, the processing station 50 has an electrical system including a first electrode configured to contact the workpiece and a second electrode disposed in the vessel 54. The first and second electrodes establish an electrical field to plate ions in an electrolytic solution onto the workpiece. It will be appreciated that the electrochemical processing chamber 50 can be an electroless chamber that does not include an electrical system with first and second electrodes. Suitable electrochemical deposition chambers are disclosed in (a) U.S. Pat. Nos. 6,569,297 and 6,660,137; and (b) U.S. Publication Nos. 2003/0068837; 2003/0079989; 2003/0057093; 2003/0070918; 2002/0032499; 2002/0139678; 2002/0125141; 2001/0032788; 2003/0127337; and 2004/0013808, all of which are herein incorporated by reference in their entirety. In other embodiments, the wet chemical processing chambers can be capsules or other types of chambers for cleaning wafers, such as those shown in U.S. Pat. Nos. 6,350,319; 6,423,642; and 6,413,436, all of which are herein incorporated by reference in their entirety. In still further embodiments, the processing stations can be annealing stations, metrology stations, or other types of tools for evaluating or further processing the workpieces. Suitable annealing stations, for example, are disclosed in U.S. patent application Ser. No. 10/987,049 filed on Nov. 12, 2004 and U.S. Pat. No. 6,780,374 filed on Dec. 8, 2000, which are incorporated by reference herein in their entirety.

The modular tool unit 10 can alternatively include various combinations of wet chemical processing chambers. For example, all of the chambers can be a common type (e.g., electrochemical deposition chambers, cleaning chambers, etching chambers, etc.), or various combinations of different types of chambers can be mounted to the deck 30 of the modular tool unit 10. Suitable combinations of wet chemical processing chambers are disclosed in the references incorporated above.

The transport system 60 includes a track 62 with a plurality of track interface members 63 and track fasteners 64. The track interface members 63 are arranged to engage corresponding positioning elements 34 on the platform 32 to position the track 62 at a known location in the fixed reference frame of the mounting module 20. The track 62 extends laterally along a width-wise direction W relative to the front of the modular tool unit 10 as opposed to extending axially along a depth-wise direction D of the mounting module 20. The transport system 60 can further include a robot 66 having an end-effector 68. The robot 66 moves linearly along the track 62 to move laterally between the workpiece holders 16 and/or the processing stations 50. Suitable robots and tracks are disclosed in U.S. Pat. Nos. 6,752,584 and 6,749,390, and U.S. Publication No. 2003/0159921, all of which are herein incorporated by reference in their entirety.

The transport system 60 can further include a calibration unit 69 attached to the deck 30 as shown in FIG. 1A or the platform 32 (not shown). The calibration unit 69 is fixed at a known location in the reference frame of the mounting module 20. The calibration unit 69 automatically determines the position of the robot 66 and the end-effector 68 relative to the fixed reference frame of the mounting module 20 and corrects any misalignment of the robot 66 and end-effector 68 so that the transport system 60 can accurately interface with the workpiece holders 16 and the processing stations 50 without having to manually teach the robot 66 the location of each of the components in the modular tool unit 10. Suitable calibration units and calibration methods for use with the modular tool unit 10 are disclosed in U.S. patent application Ser. Nos. 10/860,385 and 10/861,240, which are herein incorporated by reference in their entirety.

The embodiment of the modular tool unit 10 illustrated in FIG. 1A provides several advantages for tool manufacturers and microdevice manufacturers. For example, because the modular tool unit 10 has a dimensionally stable mounting module 20 and a dimensionally stable load/unload module 14, individual components can be interchanged with pre-maintained components for maintenance or repair without having to recalibrate the transport system 60 to the replacement components. This significantly reduces the downtime associated with repairing/maintaining wet chemical processing chambers such that individual chambers can be replaced as soon as they do not meet specifications. This also enables processing tools to operate at full capacity for longer periods of time compared to conventional tools that do not have a dimensionally stable mounting module. Moreover, the modular tool units 10 can be combined with one another as explained in more detail below with reference to FIG. 3 to construct custom tool configurations with two or more modular tool units 10 that have the same basic load/unload modules 14, mounting modules 20, and transport systems 60.

FIG. 1B is a top plan view of another embodiment of the modular tool unit 10. Several components of the modular tool units 10 are the same or at least substantially similar in FIGS. 1A-B, and thus like reference numbers refer to like components in these figures. The embodiment of the modular tool unit 10 illustrated in FIG. 1B has a robot 66 with dual coaxial end-effectors 68a and 68b. The end-effectors 68a-b are mounted to an arm (not shown) and rotate coaxially about a common axis A. The embodiment of the modular tool unit illustrated in FIG. 1B accordingly provides several of the same benefits as described above with reference to FIG. 1A, but also includes the additional benefits of having two end-effectors 68a-b in the same modular tool unit.

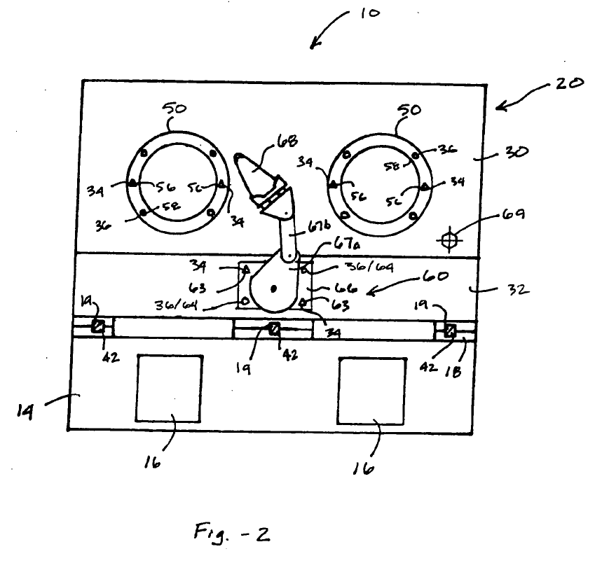

FIG. 2 is a top plan view of another embodiment of the modular tool unit 10, and like reference numbers refer to like components in FIGS. 1A-2. In this embodiment, the transport system 60 includes a multiple-link robot 66 having a base attached to the platform 32. The base can include base interface members 63 similar to the track interface members 63 described above with reference to FIGS. 1A-B. The base interface members 63 engage the positioning elements 34 on the platform 32 to position the robot 66 at a known location in the fixed reference frame of the mounting module 20. The robot 66 in this embodiment includes a multiple-link arm including a first link 67a and a second link 67b. The end-effector 68 is rotatably attached to the second link 67b. The first link 67a can rotate relative to the base, the second link 67b can rotate relative to the first link 67a, and the end-effector 68 can rotate relative to the second link 67b. The robot 66 can accordingly position the end-effector 68 at any of the workpiece holders 16 and/or processing stations 50 in the modular tool unit 10.

FIG. 3 is a top plan view of an integrated tool assembly 11 including a first modular tool unit 10a and a second modular tool unit 10b. The first and second modular tool units 10a-b can be substantially similar to the modular tool unit 10 described above with reference to FIGS. 1A-B, but the modular tool units 10a and 10b are connected together in an integrated arrangement. In this embodiment, the first modular tool unit 10a has a first side docking unit 44a with first alignment elements, and the second modular tool unit 10b has a second side docking unit 44b with second alignment elements engaged with the first alignment elements. The first and second alignment elements can be pin/hole arrangements that accurately align the first and second modular tool units 10a-b with each other so that they have a common fixed reference frame. The integrated tool assembly 11 further includes a transport system 60 having a track 62 extending along the platforms 32 of both the first and second modular tool units 10a-b. The embodiment of the transport system 60 illustrated in FIG. 3 includes a single robot 66 having dual, coaxial end-effectors 68a-b (shown superimposed with each other), but the integrated tool assembly 11 can include two or more robots 66 on the track 62. Alternatively, each modular tool unit 10a and 10b can have a separate track 62 and a separate robot 66.

The integrated tool assembly 11 can further include a load/unload module 14 attached to the first modular tool unit 10a as described above with reference to FIG. 1A. Alternatively, the integrated tool assembly 11 can include a second load/unload module (not shown) attached to the second modular tool unit 10b for additional capacity.

The first modular tool unit 10a can include first processing stations 50a, and the second modular tool unit 10b can include second processing stations 50b. The processing stations 50a and 50b can be identical stations that perform identical functions. Alternatively, the first processing stations 50a can be different than the second processing stations 50b. For example, the first processing stations 50a can be electrochemical deposition chambers having an alkaline bath for electrochemically repairing, enhancing, or otherwise manipulating a seed layer, or directly plating onto a barrier layer, as disclosed in U.S. Pat. Nos. 6,197,181, 6,290,833 and 6,565,729, which are herein incorporated by reference. The first processing stations 50a can accordingly be electroplating chambers and/or electroless plating chambers. The second processing stations 50b can be electrochemical deposition chambers having an acid processing solution. Such an integrated tool assembly 11 could accordingly perform seed layer enhancement or direct barrier plating procedures in the first modular tool unit 10a, and then perform bulk plating procedures in the second modular tool unit 10b as described in U.S. Pat. Nos. 6,197,181, 6,290,833 and 6,565,729. The first processing stations 50a and/or the second processing stations 50b can alternatively be any combination of one or more annealing stations, metrology stations, rinse stations, etch stations, electroplating chambers, and/or electroless plating chambers. The processing sections of modular tool units 10a and 10b can be separated by a dividing wall between the first and second side docking units 44a and 44b to maintain generally separate cells between the alkaline chemistry in the first modular tool unit 10a and the acidic chemistry in the second modular tool unit 10b . It will be appreciated that many other configurations of tool assemblies can be constructed using two more modular tool units 10 with the desired combination of processing stations and robots to provide the desired functionality and capacity for individual customers.

### B. Specific Embodiments of Modular Tool Units

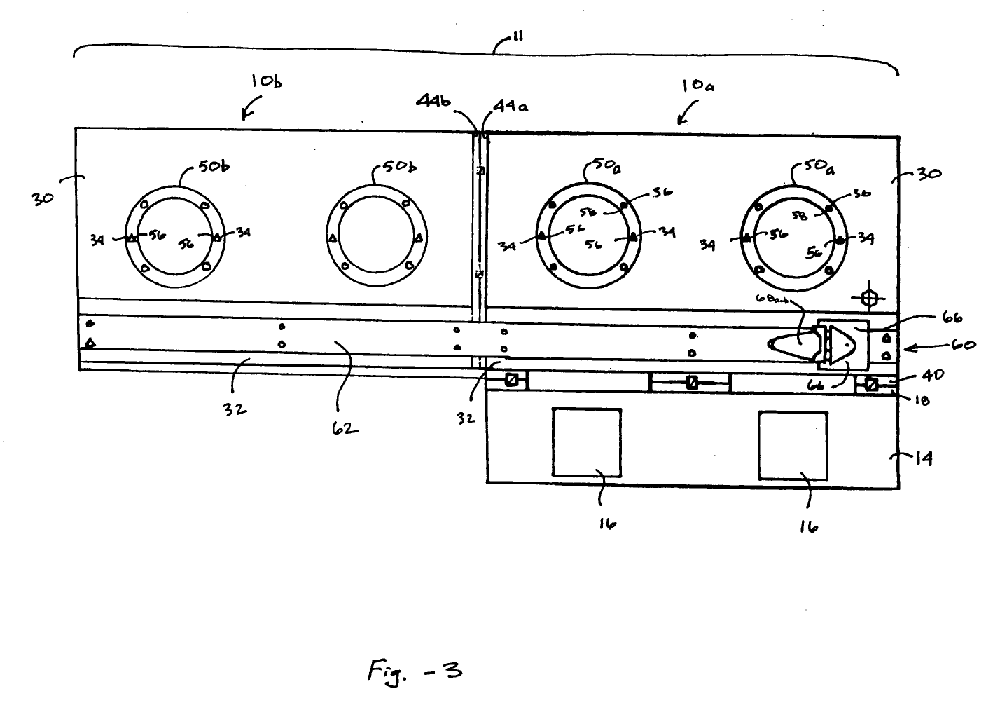

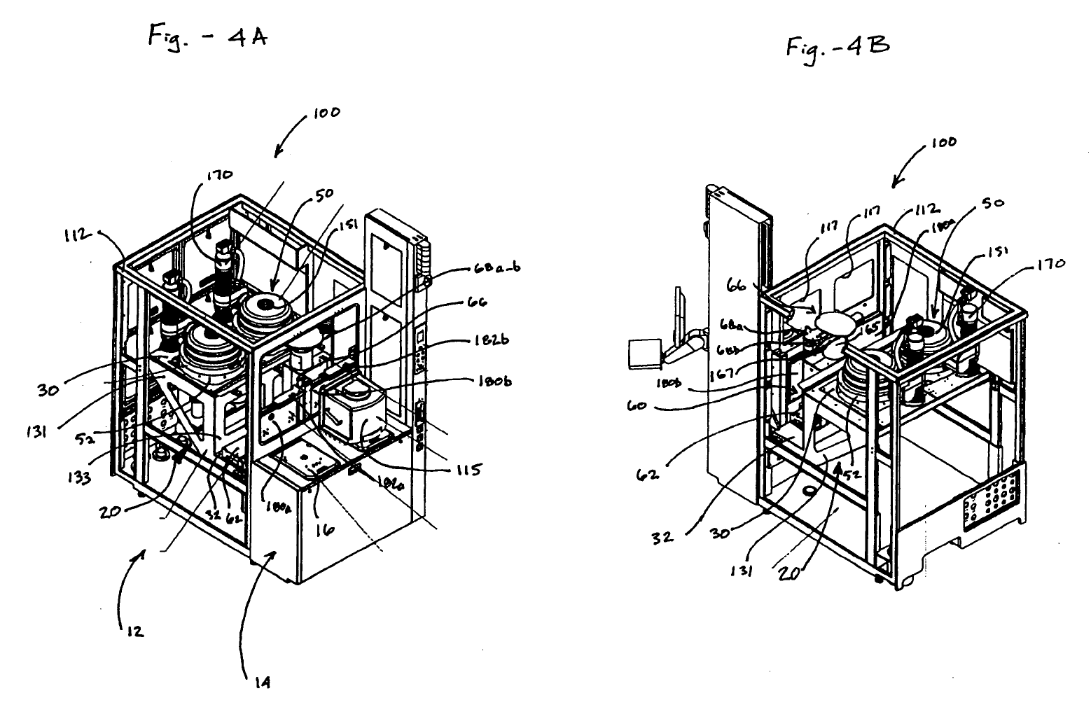

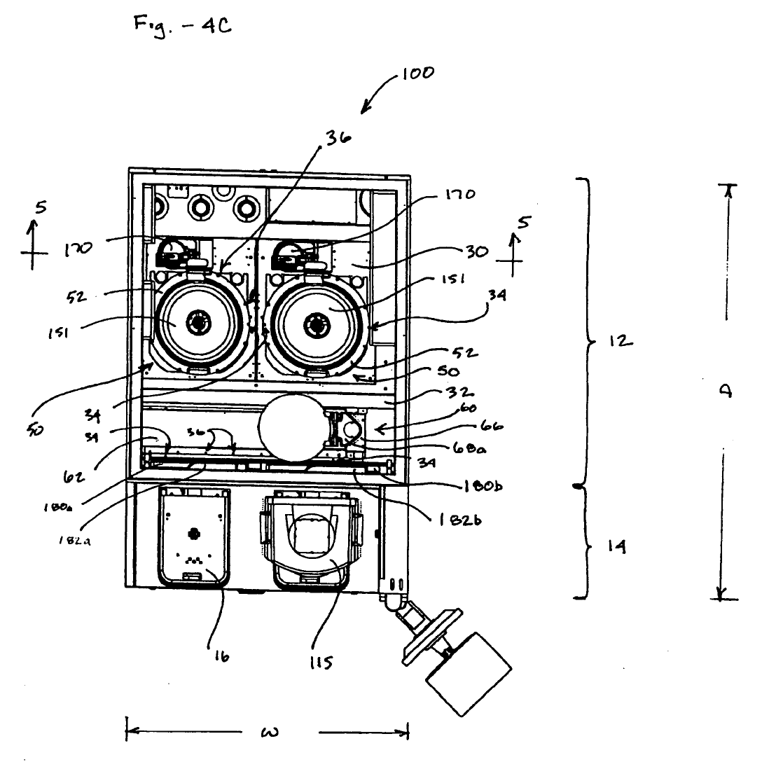

FIG. 4A is a front isometric view, FIG. 4B is a rear isometric view, and FIG. 4C is a top plan view of a modular tool unit 100 in accordance with a specific embodiment of the invention that relates to the modular tool unit 10 in FIG. 1B. Accordingly, like reference numbers refer to like components in FIGS. 1A-4C. The modular tool unit 100 illustrated in FIGS. 4A-C includes a frame 112 to carry the mounting module 20. The frame 112 can further include leveling jacks to adjust the plane of the mounting module 20.

As shown in FIGS. 4A-C, the load/unload module 14 is fixedly attached to the processing module 12 at the docking stations (not shown in FIGS. 4A-C) as described above. The load/unload module 14 can include two workpiece holders 16 that carry cassettes or pods 115. The workpiece holders 16 can move to a lowered position for manually loading/unloading the pods 115 onto the workpiece holders 16. The workpiece holders 16 accordingly provide an ergonomic elevation for manual loading/unloading of the pods 115. The workpiece holders 16 also lift the pods 115 to a raised position for positioning the pods 115 at access openings 117 (shown in FIG. 4B only).

The mounting module 20 shown in FIGS. 4A-B includes the deck 30 and the platform 32. In this embodiment, the deck 30 is elevated with respect to the platform 32, and the track 62 extends in a width-wise direction W (see FIG. 4C) along the platform 32. The robot 66 accordingly moves laterally with respect to a depth-wise direction D (FIG. 4C).

Referring to FIG. 4C, the deck 30 and the platform 32 include several positioning elements 34 and attachment elements 36 that accurately position the processing stations 50 and the track 62 at known locations within the reference frame of the mounting module 20. More specifically, the embodiment of the modular tool unit 100 illustrated in FIG. 4C includes two positioning elements 34 on opposing sides of each processing station 50 and a plurality of attachment elements 36 around each of the processing stations 50. The platform 32 also includes several positioning elements 34 and attachment elements 36. The positioning elements 34 are engaged with interface elements of the processing stations 50 and the track 62 to position these components in the fixed reference frame of the mounting module 20 with a high degree of accuracy as described above.

The mounting module 20 illustrated in FIGS. 4A-B further includes side panels 131 and a front panel 133 (FIG. 4A only). The deck 30, platform 32, side panels 131 and front panel 133 are made from rigid, dimensionally stable materials, and these components are fixed together to define the fixed reference frame of the modular tool unit 100. The deck 30, platform 32, side panels 131 and front panel 133, can be made from stainless steel, other metal alloys, solid cast materials, or fiber-reinforced composites. For example, these components can be made from a Nitronic 50 stainless steel, Hastelloy 625 steel alloys, or a solid cast epoxy filled with mica. The fiber-reinforced composites can include a carbon-fiber or Kevlar®) mesh in a hardened resin. The materials for these components should also be compatible with the chemicals used in the wet chemical processes. Stainless steel is well suited for many applications because it is strong, but not affected by many of the electrolytic solutions or cleaning solutions used in wet chemical processes. In one embodiment, these components are 0.125-0.375 inch thick stainless steel members, and more specifically, they can be 0.25 inch thick stainless steel members. These components, however, can have different thicknesses in other embodiments.

### C. Embodiments of Mounting Modules

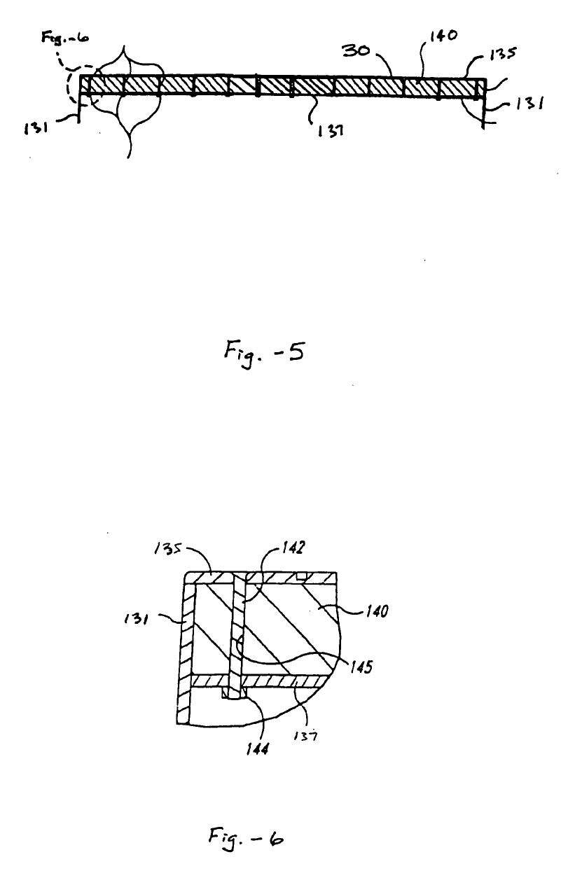

FIG. 5 is a cross-sectional view taken along line 5-5 of FIG. 4C illustrating one suitable embodiment of the integral structure for the deck 30, and FIG. 6 is a detailed view of a portion of the deck shown in FIG. 5. In this embodiment, the deck 30 includes bracing 140, such as joists, extending laterally between the side panels 131. The deck 30 further includes a first panel 135 attached to the upper side of the bracing 140, and a second panel 137 attached to the lower side of the bracing 140. The deck 130 can further include a plurality of through bolts 142 and nuts 144 that secure the first and second panels 135 and 137 to the bracing 140. As best shown in FIG. 6, the bracing 140 has a plurality of holes 145 that receive the through bolts 142. The nuts 144 can be welded to the bolts 142 to enhance the connection between these components.

Referring again to FIGS. 4A-C, the processing stations 50 can be electrochemical deposition chambers, cleaning capsules, annealing stations, metrology stations, cleaning/etching capsules, and/or other types of processing stations. The processing stations 50 further include a head 151 having a workpiece holder (not shown) that positions the workpiece relative to the vessels (not shown). The heads 151 are typically raised and lowered relative to the deck 30 for loading/unloading workpieces into the processing stations 50. As such, the modular tool unit 100 can further include a plurality of lift units 170 fixedly attached to the deck 30. The lift units 170 can be lift-rotate units that not only raise and lower the heads 151, but also rotate the heads about horizontal axes between a faceup and a facedown position. Each lift unit 170 further includes a flange with interface members and fasteners for fixedly attaching the lift unit 170 at a known location relative to the deck 30. The interface between the lift units 170 and the deck 30 can be substantially similar to that of the interface between the processing stations 50 and the deck 30 such that the positions of the heads 151 are at known locations in the fixed reference frame of the mounting module 20.

Referring to FIG. 4B, the robot 66 of the transport system 60 can include a waist member 165 (FIG. 4B) and a single-link arm 167 fixedly attached to the waist member 165. The single-link arm 167 has only one link that is fixedly attached to the waist member 165 such that the single-link arm 167 rotates with the waist member 165. The robot 66 further includes first and second end-effectors 68a-b rotatably attached to the single-link arm 167 to rotate coaxially about a common rotation axis. The robot 66 with the single-link arm 167 and the dual coaxial end-effectors 68a-b are described in more detail in U.S. Pat. Nos. 6,752,584 and 6,749,390, and U.S. patent application Ser. No. 60/586,514, entitled Transfer Devices And Methods For Handling Microfeature Workpieces Within An Environment Of A Processing Machine, filed on Jul. 9, 2004 (Perkins Coie Ref. No. 29195.8247.US00), which is herein incorporated by reference.

### D. Embodiments of Door Assemblies

The modular tool unit 100 can further include door assemblies 180a and 180b for closing the openings 117 (shown in FIG. 4B only) and scanning the wafers within the pods 115 (FIGS. 4A and 4C). The door assemblies 180a and 180b further include scanners 182a and 182b (FIGS. 4A and 4C) for optically and/or electronically scanning the workpieces within the pods 115 as the door assemblies 180a-b move between a closed position and an open position. More specifically, after a pod 115 (FIG. 4A) has been engaged with the outer wall around an opening 117 (FIG. 4B), the corresponding door assembly opens a door of the pod 115 and moves downwardly into an interior pocket (not shown) so that the pod door is protected and the interior of the pod 115 is opened to the interior of the modular tool unit 100. The door assemblies 180a-b maintain the environments in both the modular tool unit 100 and the pods 115 at clean standards. An example of a pod for 300 mm workpieces and the interface between the pod 115 and similar door assemblies are described in U.S. Pat. No. 6,717,171, which is herein incorporated by reference. The transport system 60 can then control the end-effector 68 for ingress/egress through the opening 117 to the pod 115.

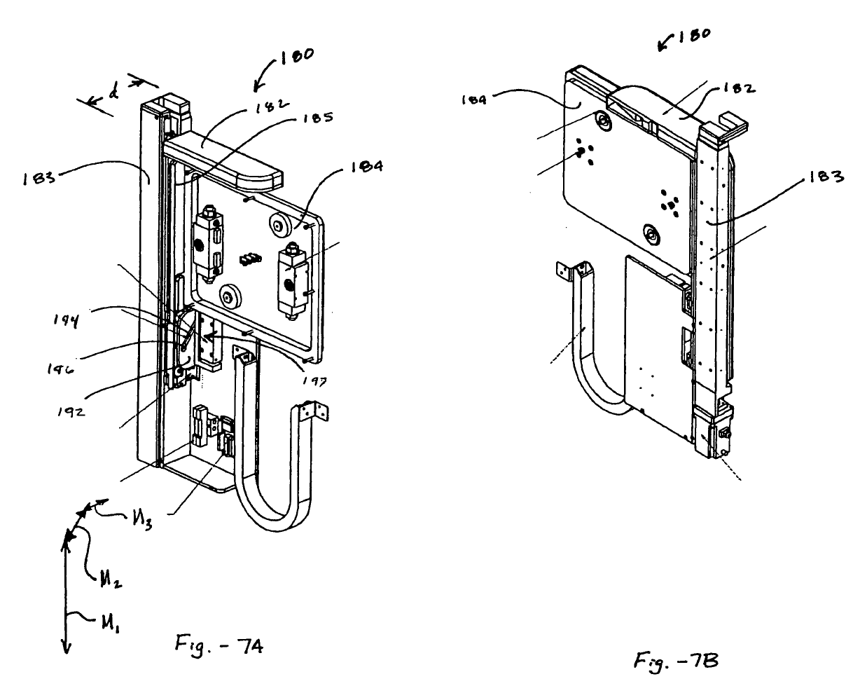

FIG. 7A is a rear isometric view and FIG. 7B is a front isometric view of one of the door assemblies 180 described above with reference to FIGS. 4A-C. The door assembly 180 includes the scanner 182, a guide track 183, and a door panel 184 that moves relative to the guide track 183. The guide track 183 is fixed to the load/unload module 14 (FIG. 4C). The door assembly 180 further includes a carriage 185 slidably attached to the guide track 183, and an actuator assembly 190 attached to the carriage 185. The actuator assembly 190 includes a motor (not shown) that moves the door panel 184 vertically with respect to the carriage 185. The actuator assembly 190 further includes a cam follower 192 having an angled slot 194 and a cam 196 received within the slot 194. The motor 190 moves the cam follower 192 and the door panel 184 so that the cam follower 192 rides along the cam 196.

The door assembly 180 operates to raise/lower the door panel 184 and move the door panel 184 laterally in a depth-wise direction “d” with respect to the guide track 183. More specifically, the carriage 185 moves vertically (arrow M₁) along the guide track 183 until the door panel 184 is raised to approximately the level of the opening 117 (FIG. 4B). At this point, the actuator assembly 190 raises the cam follower 192 and the door panel 184 such that the cam 196 moves the door laterally along a second movement (arrow M₂) and then a third movement (arrow M₃). The slot 194 is configured with two different segments at different angles to accordingly drive the door panel 184 along the second movement M₂ and the third movement M₃. This process is reversed to lower the door panel 104 and open the opening 117.

The door assembly 180 illustrated in FIGS. 7A and 7B opens and closes the door panel 184 in a limited lateral stroke. As such, the door assembly 180 only requires a slight depth in the depth-wise direction “d” to operate between open-and closed positions. This is advantageous because it reduces the overall depth D (FIG. 4C) of the modular tool unit. One modular tool unit manufactured by Semitool, Inc., for example, reduces the overall depth D of the modular tool unit by approximately 5 inches with the door assembly 180 illustrated in FIGS. 7A and 7B.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

I claim:

1. A modular tool unit for processing of microfeature workpieces, comprising:
a dimensionally stable mounting module defining a fixed reference frame, the mounting module having front alignment elements at predetermined locations for referencing a load/unload module with the fixed reference frame, positioning elements at predetermined locations in the fixed reference frame, and attachment elements;
a processing station having a chamber interface member engaged with one of the positioning elements to position the station at a predetermined location in the reference frame and a chamber fastener engaged with one of the attachment elements to secure the station to the mounting module; and
a transport system having a transport interface member engaged with one of the positioning elements to position the transport system at a predetermined location in the reference frame and a transport fastener engaged with one of the attachment elements to secure the transport system to the mounting module, wherein the mounting module is configured to maintain relative positions between the front alignment elements and the positioning elements in the fixed reference frame such that the transport system can be automatically calibrated to the processing station.

2. The modular tool unit of claim 1, further comprising a dimensionally stable load/unload module having a first docking unit with first alignment elements arranged in a pattern of the predetermined locations of the front alignment elements and engaged with the front alignment elements.

3. The modular tool unit of claim 1 wherein the processing station comprises a first wet chemical processing chamber, and wherein the modular tool unit further comprises a second wet chemical processing chamber attached to the mounting module, the second wet chemical processing chamber having a chamber interface member engaged with one of the positioning elements and a chamber fastener engaged with one of the attachment elements.

4. The modular tool unit of claim 3 wherein the first and second wet chemical processing chambers comprise electrochemical deposition chambers for electrochemically depositing material onto microfeature workpieces.

5. The modular tool unit of claim 3 wherein the first and second wet chemical processing chambers comprise surface cleaning chambers for cleaning a surface of microfeature workpieces.

6. The modular tool unit of claim 3 wherein the first and second wet chemical processing chambers are the only wet chemical processing chambers mounted to the mounting module.

7. The modular tool unit of claim 1 wherein:
the mounting module has a front section, a width laterally across the front section, a processing section, and a depth from the front section to a backside of the processing section;
the front section of the mounting module further comprises a platform extending laterally in a widthwise direction, the platform having a plurality of the positioning elements and a plurality of the attachment elements;
the processing section further comprises a deck having a plurality of the positioning elements, a plurality of the attachment elements, and apertures through which a portion of the wet chemical processing chambers extend; and
the processing station comprises a first wet chemical processing chamber attached to the deck and the tool further comprises a second wet chemical processing chamber attached to the deck, the second wet chemical processing chamber having a chamber interface member engaged with one of the positioning elements at the deck and a chamber fastener engaged with one of the attachment elements at the deck.

8. The modular tool unit of claim 7 wherein the deck comprises a rigid first panel having positioning elements and attachment elements, a rigid second panel juxtaposed to the first panel, and braces between the first and second panels, wherein the first panel, the second panel and the braces are fastened together.

9. The modular tool unit of claim 7 wherein the transport system further comprises:
a linear track having track interface members engaged with positioning elements at the platform and track fasteners engaged with attachment elements at the platform, the track extending laterally in the widthwise direction; and
a robot moveably carried by the track to move laterally in the width-wise direction, the robot having a rotatable waist member, an arm attached to the waist member, a first end-effector rotatably attached to the arm to rotate about a rotation axis, and a second end-effector carried by the arm to coaxially rotate about the rotation axis.

10. The modular tool unit of claim 9 wherein the arm has a single link and the single link is fixedly attached to the waist member.

11. The modular tool unit of claim 7 wherein the transport system further comprises a robot attached to the platform, the robot having a waist member, an arm including a first link fixedly attached to the waist member and a second link rotatably attached to the first link, and an end-effector rotatably attached to the second link.

12. A modular tool unit for processing of microfeature workpieces, comprising:
a dimensionally stable mounting module defining a fixed reference frame and including front alignment elements at predetermined locations, a platform extending laterally in a width-wise direction, a deck behind the platform, positioning elements at the platform and the deck, and attachment elements at the platform and the deck;
a processing station attached to the deck, the processing station having a chamber interface member engaged with one of the positioning elements at the deck and a chamber fastener engaged with one of the attachment elements at the deck;
a transport system having a track attached to the platform and a robot mounted to the track to translate linearly along the track, wherein the track extends width-wise relative to the mounting module and includes a track interface member engaged with one of the positioning elements at the platform and a track fastener engaged with one of the attachment elements at the platform, wherein the mounting module is configured to maintain relative positions between the front alignment elements and the positioning elements in the reference frame such that the transport robot can be automatically calibrated to the processing station.

13. The modular tool unit of claim 12, further comprising a dimensionally stable load/unload module having a first docking unit with first alignment elements arranged in a pattern of the predetermined locations of the front alignment elements and engaged with the front alignment elements.

14. The modular tool unit of claim 12 wherein the processing station comprises a first wet chemical processing chamber, and wherein the modular tool unit further comprises a second wet chemical processing chamber attached to the deck, the second wet chemical processing chamber having a chamber interface member engaged with one of the positioning elements and a chamber fastener engaged with one of the attachment elements.

15. The modular tool unit of claim 14 wherein the first and second wet chemical processing chambers comprise electrochemical deposition chambers for electrochemically depositing material onto microfeature workpieces.

16. The modular tool unit of claim 14 wherein the first and second wet chemical processing chambers comprise surface cleaning chambers for cleaning a surface of microfeature workpieces.

17. The modular tool unit of claim 14 wherein the first and second wet chemical processing chambers are the only wet chemical processing chambers mounted to the mounting module.

18. The modular tool unit of claim 12 wherein the deck comprises a rigid first panel having positioning elements and attachment elements, a rigid second panel juxtaposed to the first panel, and braces between the first and second panels, wherein the first panel, the second panel and the braces are fastened together.

19. The modular tool unit of claim 12 wherein the robot further comprises a waist member, an arm fixedly attached to the waist member, a first end-effector attached directly to the arm without an intervening link pivotally attached between the arm and the first end-effector, and a second end-effector attached to the arm to rotate coaxially with the first end-effector.

20. The modular tool unit of claim 12 wherein the robot further comprises a waist member, an arm including a first link fixedly attached to the waist member and a second link rotatably attached to the first link, and an end-effector rotatably attached to the second link.

21. A modular tool unit for wet chemical processing of microfeature workpieces, comprising:
a dimensionally stable first mounting module defining a fixed first reference frame and including first front alignment elements at predetermined locations in the first reference frame, a first side docking unit having first side alignment elements at predetermined locations in the first reference frame, a first processing section, first positioning elements, and first attachment elements;
a dimensionally stable second mounting module defining a fixed second reference frame and including a second side docking unit with second side alignment elements at predetermined locations in the second reference frame, a second process section, second positioning elements, and second attachment elements, wherein the second alignment elements of the side docking unit are mated with the first alignment elements of the first docking unit to register the second reference frame with the first reference frame,
a first wet chemical processing chamber attached to the first processing section of the first mounting module, the first wet chemical processing chamber having chamber interface members engaged with the first positioning elements and chamber fasteners engaged with the first attachment elements;
a second wet chemical processing chamber attached to the second processing section of the second mounting module, the second wet chemical processing chamber having chamber interface members engaged with the second positioning elements and chamber fasteners engaged with the second attachment elements; and
a transport system including a track attached to the first mounting module and the second mounting module, track interface members engaged with first and second positioning elements, and track fasteners engaged with first and second attachment elements, wherein the track extends laterally along the first and second mounting modules.

22. The modular tool unit of claim 21 wherein the first wet chemical processing chamber comprises an electrochemical deposition chamber including an alkaline processing solution, and wherein the second wet chemical processing chamber comprises an electrochemical deposition chamber including an acidic processing solution.

23. The modular tool unit of claim 21 wherein the first wet chemical processing chamber comprises an electrochemical deposition chamber, and wherein the second wet chemical processing chamber comprises a surface cleaning chamber.

24. The modular tool unit of claim 21, further comprising a dimensionally stable load/unload module having a first docking unit with first alignment elements arranged in a pattern of the predetermined location of the front alignment elements and engaged with the front alignment elements.

25. The modular tool unit of claim 21 wherein the first and second mounting modules each include a deck comprising a rigid first panel having positioning elements and attachment elements, a rigid second panel juxtaposed to the first panel, and braces between the first and second panels, wherein the first panel, the second panel and the braces are fastened together.

26. The modular tool unit of claim 21 wherein the transport system further comprises a robot having a waist member, an arm fixedly attached to the waist member, a first end-effector attached directly to the arm without an intervening link pivotally attached between the arm and the first end-effector, and a second end-effector attached to the arm to rotate coaxially with the first end-effector.

27. The modular tool unit of claim 21 wherein the transport system further comprises a robot having a waist member, an arm including a first link fixedly attached to the waist member and a second link rotatably attached to the first link, and an end-effector rotatably attached to the second link.

28. A modular tool unit for processing of microfeature workpieces, comprising:
a first mounting module having a fixed reference frame, a side docking unit having side alignment elements at predetermined locations in the reference frame, and positioning elements at other predetermined locations in the reference frame, wherein the side docking unit is configured to align another modular tool unit with the fixed reference frame of the first mounting module; and
a processing station having an interface element engaged with one of the positioning elements to position the processing station at a known location in the reference frame.

29. A method of manufacturing an integrated tool assembly, comprising:
providing a first modular tool unit having a first mounting module that defines a fixed first reference frame and a first processing station carried by the first mounting module;
providing a second modular tool unit having a second mounting module that defines a fixed second reference frame and a second processing station carried by the second mounting module; and
connecting the first modular tool unit to the second modular tool unit so that the first and second reference frames are registered with each other.

30. The method of claim 29 wherein connecting the first modular tool unit to the second modular tool unit comprises mating first alignment elements of the first mounting module with second alignment element of the second mounting module, the first alignment elements being at predetermined locations in the first reference frame and the second alignment elements being at predetermined location in the second reference frame.

31. The method of claim 29, further comprising attaching a transport system to the first and second mounting modules to operate with the first and second processing stations.

32. The method of claim 29, further comprising attaching a load/unload module to the first modular tool unit so that the load/unload module is registered with the first reference frame.

33. The method of claim 29, further comprising attaching a transport system to the first and second mounting modules and automatically calibrating the transport system to operate with the first and second processing stations.

34. The method of claim 29 wherein the first processing station comprises a wet chemical processing chamber.

35. The method of claim 29 wherein the first processing station comprises a wet chemical processing chamber and the second processing station comprises an annealing chamber.
